(19) United States
(12) Patent Application Publication
(10) Pub. No.: US 2006/0013276 A1
(43) Pub. Date: Jan. 19, 2006

(54) VCSEL having an air gap and protective coating

(76) Inventor: Scott A. McHugo, Menlo Park, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/892,983

(22) Filed: Jul. 15, 2004

(51) Int. Cl. H01S 5/00

(52) U.S. Cl. 372/50.124

(57) ABSTRACT

A VCSEL includes a gap in a mirror stack and a protective layer sealing an end of the gap. The gap defines a boundary of the aperture of the VCSEL without introducing the stresses that oxide regions in oxide VCSELs can cause, and the protective layer, which can be a thin dielectric layer, shields the mirror stack from environmental damage. The VCSEL can thus achieve high reliability. A fabrication process for the VCSEL forms an oxidation hole, oxidizes a portion of an aluminum-rich layer in a mirror stack of the VCSEL exposed in the hole, and then removes all or some of the resulting oxide to form the desired gap. The protective layer can then be deposited to seal an end of the gap.

### BACKGROUND

Vertical cavity surface emitting lasers (VCSELs) are well-known optoelectronic devices that can be manufactured using semiconductor processing techniques. FIG. 1, for example, shows a cross-sectional view of a conventional oxide VCSEL 100 that includes a cavity layer 120 sandwiched between a partially reflective mirror stack 110 and a highly reflective mirror stack 130. Cavity layer 120 generally contains a lasing material such as gallium arsenide that emits light where an electrical current passes through cavity layer 120. Mirror stacks 110 and 120 normally have reflectivities and separations selected to achieve a desired gain for the operating light wavelength in VCSEL 100 and are preferably conductive and in contact with the electrical terminals (not shown) of VCSEL 100.

An insulating oxide region 112 in mirror stack 110 defines the boundaries of an aperture through which the light beam from VCSEL 100 emerges. To confine the light beam, oxide region 112 channels the current flow into cavity layer 120 to the area where light emissions are desired. Oxide region 112 may also change the reflectivity/refractive index of mirror stack 110 outside the area of aperture 140 so that the optimal gain is limited to the area of aperture 140.

Before being sold as a commercial product, VCSELs such as oxide VCSEL 100 generally must pass a reliability test that attempts to identify devices that may have short useful lives or that may fail in some working environments. One such test, commonly known as the 85/85 stress test or Wet High Temperature Operating Life test (WHTOL), is used industry-wide to assess the reliability of VCSELs as well as others optoelectronic devices. Typically, oxide VCSELs rapidly fail the 85/85 stress test.

Structures and processing techniques that can improve the yield of VCSELs capable of passing the required reliability tests are thus desired.

### SUMMARY

In accordance with an aspect of the invention, a VCSEL uses a void or gap in a mirror stack to define a light aperture and a thin protective layer to cover the gap. With the protective layer, the VCSEL can pass the 85/85 stress tests and provide high reliability. Further, the manufacturing process for the thin layer avoids problems associated with forming thick protective layers.

One specific embodiment of the invention is a device such as a VCSEL that includes a first mirror stack, a second mirror stack, a cavity layer, and a protective layer. The cavity layer is between the first mirror stack and the second mirror stack. A hole extends through the first mirror stack, and a gap extends from a sidewall of the hole into the first mirror stack to define boundaries of an aperture of the device. The protective layer seals an end of the gap at the sidewall of the hole in the first mirror layer.

Another specific embodiment of the invention is a fabrication process for a device such as a VCSEL. The process generally includes: forming a first mirror stack, a cavity layer, and a second mirror stack on a substrate; etching a hole in the first mirror stack; removing a portion of a layer in the first mirror stack to form a gap extending from a sidewall of the hole into the first mirror stack; and depositing a protective layer that seals an end of the gap at the sidewall of the hole. Forming the gap can include oxidizing the layer in the first mirror stack to form an oxide region and then etching away at least a portion of the oxide region.

### BRIEF DESCRIPTION OF THE DRAWINGS

FIG. 1 shows a conventional oxide VCSEL.

FIG. 2 shows a VCSEL in accordance with an embodiment of the invention including a thin layer that seals a gap used to define an aperture of the VCSEL.

FIGS. 3A, 3B, 3C, 3D, and 3E illustrate a process for forming the VCSEL of FIG. 2.

FIG. 4 shows a top view of a VCSEL in accordance with an embodiment of the invention.

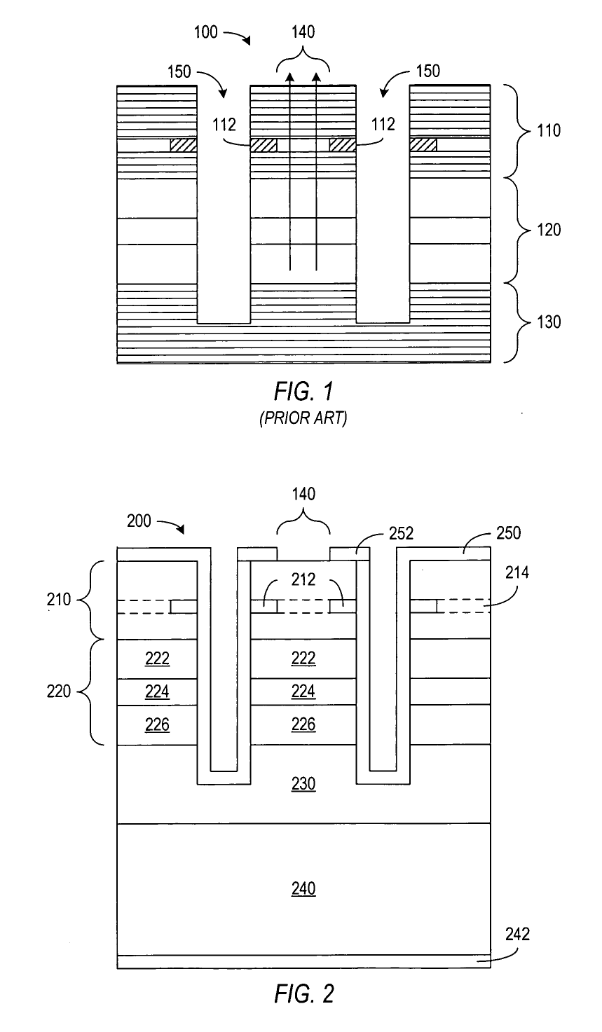

Use of the same reference symbols in different figures indicates similar or identical items.

### DETAILED DESCRIPTION

In accordance with an aspect of the invention, a vertical cavity surface emitting laser (VCSEL) having a gap defining the boundaries of an aperture and a thin protective layer protecting the gap provides high reliability. Manufacturing techniques for such VCSELs provide a high yield of devices that pass industry standard reliability tests such as the 85/85 stress test.

FIG. 2 shows a cross-section of a VCSEL 200 in accordance with an embodiment of the invention. VCSEL 200 includes a top mirror stack 210, a cavity layer 220, and a bottom mirror stack 230 that are formed on an underlying substrate 240. A protective layer 250 covers at least selected portions of cavity layer 220 and mirror stacks 210 and 230, and particularly seals a gap 212 that defines boundaries of an aperture of VCSEL 200.

In the illustrated embodiment, cavity layer 220 includes one or more active layers 224 (e.g., one or more quantum wells and/or one or more quantum dots) that are sandwiched between spacer layers 222 and 226. Alternatively, active layer 224 could be located above or below a single spacer layer. Active layer 224 can be formed from a variety of materials including but not limited to GaAs, InGaAs, AlInGaAs, AlGaAs, InGaAsP, GaAsP, GaP, GaSb, GaAsSb, GaN, GaAsN, InGaAsN, and AlInGaAsP. Other quantum well layer compositions also may be used. Spacer layers 222 and 226 are generally formed from materials chosen based upon the composition of active layer 224.

Cavity layer 220 has an overall thickness selected according to the operational wavelength of light emitted from VCSEL 200. To produce a light beam from VCSEL 200, a driving circuit (not shown) drives a current through active layer 224. For connection to a drive circuit, VCSEL 200 has a first electrical contact 252 above mirror stack 210 and a second electrical contact 242 below active layer 220. However, VCSEL 200 could alternatively employ contacts with other configurations. For example, the second electrical contact could be on top of VCSEL 200 or within bottom mirror stack 230. In whichever contact configuration used, an operating voltage applied between electrical contacts 242 and 252 preferably produces a current flow in VCSEL 200 through mirror stack 210 and cavity layer 220, causing lasing in active layer 224.

Gap 212 is formed in an aluminum-rich layer 214 of mirror stack 210 to create a confinement region that laterally confines the flow of charge carriers and photons in VCSEL 200. Layer 214 can be located anywhere in mirror stack 210, including the top or bottom of mirror stack 210. In some embodiments, gap 212 circumscribes a central aperture through which current and light preferably flow. Charge carrier confinement results from the relatively high electrical resistivity of gap 212, which causes electrical current to flow through a centrally located region of VCSEL 200. Optical confinement results from the low refractive index of gap 212, which creates a lateral refractive index profile that guides the photons that are generated in cavity layer 220. The carrier and optical lateral confinement increases the density of carriers and photons within an active region of layer 224 and increases the efficiency of light generation within the active region.

Mirror stacks 210 and 230 each includes a system of alternating layers of different refractive index that preferably forms a distributed Bragg reflector (DBR) designed for the operating laser wavelength (e.g., a wavelength in the range of 650 nm to 1650 nm). For example, mirror stacks 210 and 230 may include layers of aluminum gallium arsenide (AlGaAs) where the aluminum content of the layers alternates between higher and lower levels. Each layer of mirror stack 210 or 230 in a conventional stack typically has an effective optical thickness (i.e., the layer thickness multiplied by the refractive index of the layer) that is about one-quarter of the operating laser wavelength. One particular layer 214 in mirror stack 210 contains an aluminum-rich material with an aluminum content that is sufficiently high that layer 214 oxides much more quickly than the other layers of mirror stack 210. In a typical implementation, layer 214 may be about 95 to 98% aluminum, while the alternating layers have aluminum content that typically varies between around 20% and 80%.

In the illustrative embodiment of FIG. 2, mirror stacks 210 and 230 are designed so that VCSEL 200 emits light through mirror stack 210. In other embodiments of the invention, mirror stacks 210 and 230 may be designed so that the VCSEL emits laser light through mirror stack 230 and substrate 240.

Substrate 240, which provides structural support for VCSEL 200, can be made of a variety of materials including but not limited to GaAs, InP, sapphire (Al₂O₃), or InGaAs and may be undoped, doped n-type (e.g., with Si) or doped p-type (e.g., with Zn). A buffer layer (not shown) of a material such as GaAs or AlGaAs about 100 angstroms thick can be grown on substrate 240 before other layers of VCSEL 200 to improve bonding to substrate 240. Substrate 240 is preferably conductive in the illustrated embodiment of VCSEL 200 where electrical contact 242 is on a bottom surface of substrate 240. Alternatively, substrate 240 can be made of an insulating material, and an electrical contact to cavity layer 220 or bottom mirror stack 230 can overlie substrate 240.

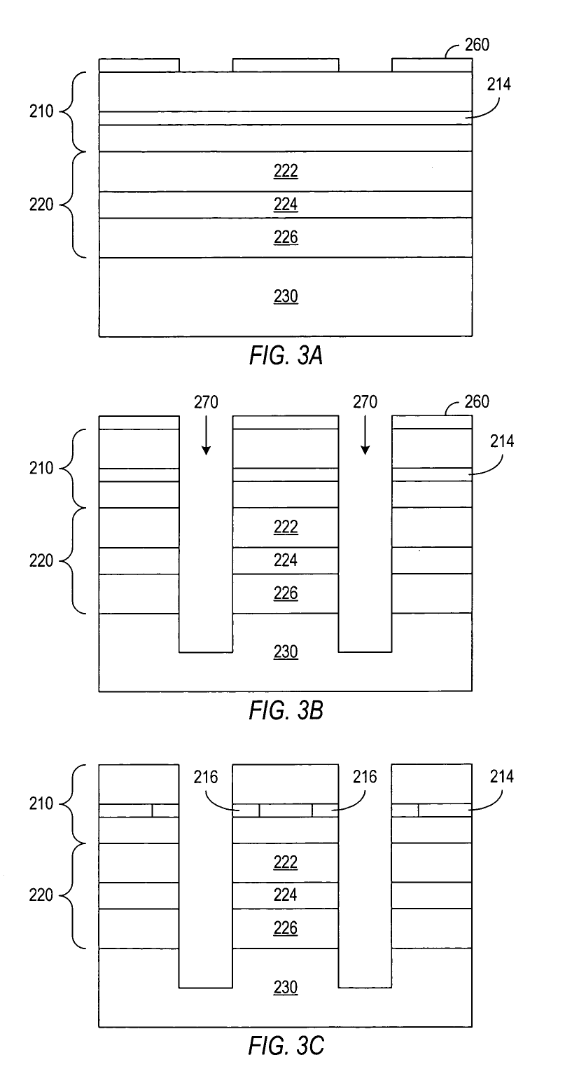

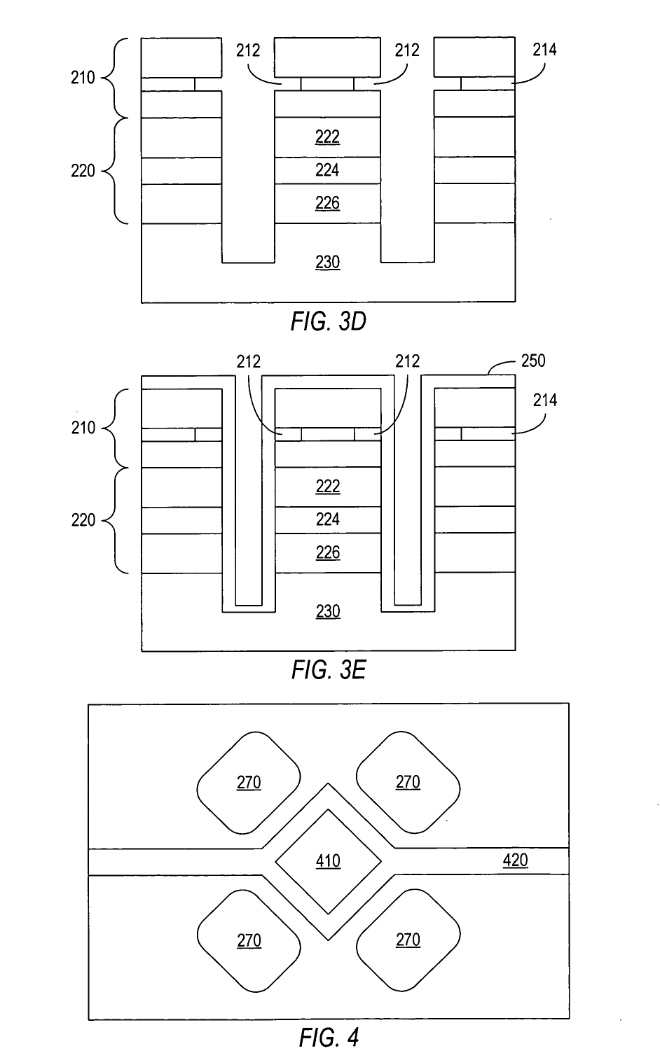

FIGS. 3A to 3E show cross-sections of intermediate structures created during a fabrication process for VCSEL 200. For ease of illustration, the underlying support substrate and the contact structure is omitted from FIGS. 3A to 3E. Contact structures for VCSELs are known in the art and can be formed using conventional techniques.

FIG. 3A shows a cross-section of a structure after formation of bottom mirror stack 230, cavity layer 220, and top mirror stack 210. Conventional epitaxial growth processes, such as metal-organic chemical vapor deposition (MOCVD) and molecular beam epitaxy (MBE) can form these layers of VCSEL 200 on the support substrate (not shown). A mask 260 having an opening (or multiple openings) is formed overlying layers 210, 220, and 230. Mask 260 can be made of photoresist or of another material such as silicon nitride (Si₃N₄) or a metal.

An etch process using mask 260 creates openings 270 as shown in FIG. 3B. Openings 270, which are commonly known as oxidation holes, extend through top mirror stack 210 and cavity layer 220 to a region in the lower mirror stack 230 of VCSEL 200 and therefore expose edges of aluminum-rich layer 214 in top mirror stack 210. More generally, oxidation holes 270 are not required to extend into lower mirror stack 230 but instead can end within cavity layer 220 or in top mirror stack 210 as long as oxide holes 270 expose aluminum-rich layer 214. Wet or dry etching process, including reactive ion etching (RIE) and reactive ion beam etching (RIBE), can form openings 270 to the required depth. In one embodiment, openings 270 leave a mesa structure in which VCSEL 200 resides.

An oxidation process using a steam or dry oxygen environment oxidizes the exposed edge of aluminum-rich layer 214 to form oxide regions 216 as shown in FIG. 3C. As noted above, the composition of aluminum-rich layer 214 is preferably high such that layer 214 is strongly oxidized while the other layers in mirror stack 210 are more slowly oxidized. For example, layer 214 may be AlGaAs that is about 95% aluminum, while other layers are AlGaAs with typically no more than about 90% aluminum. The high rate of oxidation in aluminum rich layer 214 and the duration of the oxidation process controls the lateral extent of oxide regions 216 and controls the remaining area of layer 214 that defines the aperture of VCSEL 200. In an exemplary embodiment of the invention, oxide regions 216 extend about 25 μm into layer 214, leaving an aperture about 10 to 20 μm across. Mask 260 can be removed before or after the oxidation process.

FIG. 3D shows the structure after an etching process removes oxide regions 216 leaving gaps 212 in layer 214. Oxide regions 216 can be removed using a wet etch with a basic solution such as a sodium hydroxide (NaOH) solution. In particular, a basic solution of pH greater than 13 can remove the oxide regions. As an alternative to complete removal of oxide regions 216, a partial removal of oxide region 216 could leave a portion of oxide region 216. The removal of all or part of oxide region 216 is believed to improve device reliability by reducing the stress created when oxide regions 216 form.

A thin protective layer 250 as shown in FIG. 3E is deposited over the structure or selectively in regions including oxidation holes 270. Thin layer 250 can be a silicon nitride layer having a thickness that is less than about 6000 Å, or preferably less than about 2500 Å, and more preferably is about 1100 Å thick. However, other materials such as silicon oxy-nitride (SiON) can be used for protective layer 250. Alternatively, protective layer 250 may be a composite layer, for example, including silicon nitride (Si₃N₄) layer about 1100 to 1500 Å thick, a silicon oxy-nitride (SiON) layer about 1100 to 1500 Å thick, and a titanium (Ti) layer about 700 to 1000 Å. The deposition process covers the structure/side walls of oxidation holes 270 and seals the exposed end of gap 212, leaving a seal gap (e.g., a sealed air gap). Good coverage down into holes 270 is important for reliability and can be achieved, for example, with a Plasma Enhanced Chemical Vapor Deposition (PECVD) process. An electrical contact to top mirror stack 210 can be formed before deposition of protective layer 250 or after forming openings (if necessary) where desired in protective layer 250.

The VCSEL fabrication process can be completed using conventional techniques, including, for example, backside metal deposition or metal deposition onto or within the lower mirror stack for a lower contact.

FIG. 4 shows a top view of a VCSEL 400 having a central aperture 410. An electrical contact/lines 420 include a patterned metal layer surrounding aperture 410 and in contact with the top mirror stack. Four nearly oxidation holes 270 around aperture 410 are separated from aperture 410 by a distance that is equal to or less than the lateral extend of the air gap into the top mirror stack. As a result, the air gap associated with oxidation holes 270 join together to surround aperture 410. Additionally, electrical contact/lines 420 can include a trace or metal line that runs between the oxidation holes to the area around aperture 410. Aperture 410 can be further inside the metal lines, forming concentric circles or squares.

Although the invention has been described with reference to particular embodiments, the description is only an example of the invention's application and should not be taken as a limitation. Various adaptations and combinations of features of the embodiments disclosed are within the scope of the invention as defined by the following claims.

What is claimed is:

1. A device comprising:
a first mirror stack through which a hole extends, wherein a gap extends from a sidewall of the hole into the first mirror stack;
a second mirror stack;
a cavity layer between the first mirror stack and the second mirror stack; and
a protective layer sealing an end of the gap on the sidewall of the hole in the first mirror layer.

2. The device of claim 1, wherein the device comprises a vertical cavity surface emitting laser.

3. The device of claim 1, wherein the first mirror stack comprises a plurality of layers, and the gap corresponds to a removed portion of one of the layers.

4. The device of claim 1, wherein the protective layer comprises a first dielectric layer.

5. The device of claim 4, wherein the first dielectric layer is less than about 6000 Å thick.

6. The device of claim 4, wherein the protective layer further comprises a second dielectric layer.

7. The device of claim 6, wherein:
the first dielectric layer comprises a silicon nitride layer that is on the sidewall of the hole in the first mirror stack; and
the second dielectric layer comprises a silicon oxy-nitride layer on the silicon nitride layer.

8. The device of claim 4, wherein the protective layer further comprises a metal layer.

9. The device of claim 1, wherein the first mirror stack comprises an aluminum-rich layer, and the gap corresponds a removed portion of the aluminum-rich layer.

10. The device of claim 1, wherein the gap completely surrounds an aperture of the device.

11. A fabrication process comprising:
forming a first mirror stack, a cavity layer, and a second mirror stack on a substrate;
etching a hole in the first mirror stack;
removing a portion of a layer in the first mirror stack to form a gap extending from a sidewall of the hole into the first mirror stack; and
depositing a protective layer that seals an end of the gap at the sidewall of the hole.

12. The process of claim 11, wherein forming the first mirror stack comprises forming layers of AlGaAs, wherein the layer having the portion removed is an AlGaAs layer having a highest concentration of aluminum.

13. The process of claim 12, wherein removing the portion of the layer comprises:
oxidizing the layer to form an oxide region; and
etching away at least a portion of the oxide region.

14. The process of claim 13, wherein etching away at least a portion of the oxide region comprises applying a wet etch using a high pH solution.

15. The process of claim 11, wherein depositing the protective layer comprises depositing a first dielectric layer having a thickness less than about 2500 Å.

16. The process of claim 15, wherein the protective layer comprises silicon nitride.

17. The process of claim 15, wherein depositing the protective layer further comprises depositing a second dielectric layer.

18. The process of claim 17, wherein the second dielectric layer comprises silicon oxy-nitride.

19. The process of claim 15, wherein depositing the protective layer further comprises depositing a metal layer.
